(19) United States
(12) Patent Application Publication
(10) Pub. No.: US 2009/0045437 A1
(43) Pub. Date: Feb. 19, 2009

(54) METHOD AND APPARATUS FOR FORMING A SEMI-INSULATING TRANSITION INTERFACE

(75) Inventors: Rajinder Sandhu, Castaic, CA (US); Abdullah Cavus, Redondo Beach, CA (US); Cedric Monier, Redondo Beach, CA (US); Augusto Gutierrez, Redondo Beach, CA (US)

Correspondence Address: SNELL & WILMER L.L.P. (Grumman), 600 ANTON BOULEVARD, SUITE 1400, COSTA MESA, CA, 92626, US

(73) Assignee: Northrop Grumman Space & Mission Systems Corp., Los Angeles, CA (US)

(21) Appl. No.: 11/839,488

(22) Filed: Aug. 15, 2007

(51) Int. Cl. H01L 21/20; H01L 31/00

(52) U.S. Cl. 257/190; 438/488; 257/E29.188; 257/E21.09

(57) ABSTRACT

The disclosure relates to a method for forming an intermediate lattice transition buffer layer. The method includes: (a) depositing a first graded InAlAs layer on a substrate at a first constant temperature, the first graded InAlAs layer having an In/AI composition ratio which increases across the buffer layer from a first level to a second level; (b) annealing at least the first graded InAlAs layer; (c) depositing the second graded InAlAs layer on the first graded InAlAs layer at the first constant temperature, the second graded InAlAs layer having an In/Al composition ratio which increases across the buffer layer from the second level to a third level; and (d) annealing at least the second graded InAlAs layer; the buffer layer being formed under Groups III/V overpressure.

### BACKGROUND OF THE INVENTION

1. Field of the Invention

The personal invention relates generally to improvements in enhancing the performance of semiconductor transistor devices. In this application, a heterojunction bipolar transistor device (HBT) is used for illustrating the approach.

2. Description of Related Art

Heterojunction bipolar semiconductor devices constructed on InP substrates offer higher frequency performance with lower power consumption in comparison to conventional HBT devices grown on GaAs substrates. Further enhancements can be achieved in the InP HBT device layer design by increasing the indium composition in the InAlAs/InₓGa₁₋ₓAs to that of InAs which allows for further reduction in electron effective mass, increased saturation velocity, and reduction in band gap to provide the optimal lower power high frequency performance group III-V semiconductor drive. InAlAs/InₓGa₁₋ₓAs is lattice matched to InP at X_{In}−0.53. Increasing the indium composition will lead to an increase in the lattice parameter of the InₓGa₁₋ₓAs epilayer to introduce lattice-mismatch between the InP substrate and device epilayers. In the case of RF applications the substrate of the device layers must be semi-insulating (SI) to prevent cross talk from adjacent devices in the circuit as well as reduce parasitic losses at high frequency operation. Therefore, the choice of SI substrate for the high indium content HBT devices must be developed to offer high device performance with low defect densities attributed to the lattice mismatch between the SI substrate and high indium content device layers.

Lattice-mismatched epilayers found in semiconductor devices may relax if the misfit strain energy exceeds a critical limit associated with the pseudomorphically strained epilayer thickness. Strain relieving defects such as misfit and threading dislocations are known to reduce the device high speed performance, current gain, increase junction leakage, and reduce long term reliability.

Conventional methods employed to accommodate the lattic mismatch between the SI substrate and high indium content device layers include the growth of thick (5 um) constant composition layers or growth of thick (3 um) graded composition buffer layers. The constant composition approach allows for the mismatch to be primarily accommodated at the substrate buffer layer interface. Since the strain relaxation is confined to a single interface the dislocation motion is limited by image forces from adjacent dislocations, therefore, leading to a high dislocation density in the device layers (>10⁸ cm⁻²). The graded composition buffer layer approach relies on the introduction of many interfaces combined with slow growth rates and thick buffer layer to accommodate the strain relaxation and associated dislocation motion to offer a low dislocation density template for device layer growth. This approach will lead to thick layers with high surface roughness (RMS 100 nm) associated with the dislocation motion at the multiple interfaces.

There are many shortcomings with the conventional constant composition and graded composition buffer layer strain management approaches. The primary ones include increase in device thermal resistance associated with the introduction of thick epilayer between the substrate and the active device layers. The thick buffer layers are not SI, therefore, development of a new mesa isolation device fabrication process is required to isolate devices in the circuit. The high aspect ratio of the mesa isolation can limit the circuit design complexity and compactness associated with limitations on device integration.

The approach presented in this application leverages a graded composition buffer layer approach with introduction of a nonequilibrium growth approach which employs the use of high temperature growth near the melting temperature of the epilayer, group V-III ratio optimization, and insitu annealing to enhance dislocation glide for the realization of ultra thin (<1 um), low dislocation density (10⁶ cm⁻²), with low surface roughness (4 nm).

### SUMMARY OF THE INVENTION

In one embodiment, the invention relates to a method for forming an intermediate lattice transition layer by the steps of (a) depositing a first graded InAlAs layer on a substrate at a first constant temperature, the first graded InAlAs layer having an In/Al composition ratio which increases across the graded buffer layer from a first level to a second level; (b) annealing at least the first graded InAlAs layer; (c) depositing the second graded InAlAs layer on the first graded InAlAs layer at the first constant temperature, the second graded InAlAs layer having an In/Al composition ratio which increases across the graded buffer layer from the second level to a third level; and (d) annealing at least the second graded InAlAs layer; the graded buffer layer is being formed under Groups III/V overpressure.

The invention also relates to a semiconductor having a substrate, a buffer layer and a device layer. The buffer layer is not more than 1 micron thick, with a surface roughness height of not more than 4 nm and a surface dislocation density of not more than 1×10⁶ 1/cm².

In still another embodiment, the invention relates to a method for growing a lattice transition layer having a varying lattice constant by the steps of epitaxially growing a first lattice transition sublayer over a substrate at a first temperature; annealing the first lattice transition sublayer at a second temperature to provide strain relaxation at the first lattice transition sublayer; epitaxially growing a second lattice transition sublayer over the first lattice transition sublayer at the first temperature; annealing the second lattice transition sublayer at a third temperature to provide strain relaxation at the second lattice transition sublayer; reducing the temperature to a temperature suitable for depositing a device layer; and depositing the device layer; wherein each of the first lattice transition sublayer and the second lattice transition sublayer are substantially free of threading dislocation density.

### BRIEF DESCRIPTION OF THE DRAWINGS

The exact nature of this invention, as well as the objects and advantages thereof, will become readily apparent from consideration of the following specification in conjunction with the accompanying drawings in which like reference numerals designate like parts throughout the figures thereof and wherein:

FIG. 1 is a schematic representation of a dislocation caused by sublayers having mismatching lattice constants;

FIG. 2 is a schematic representation of an exemplary heterojunction bipolar transistor according to one embodiment of the invention;

FIG. 3 is a schematic representation of a method of forming a lattice transition layer according to one embodiment of the invention;

FIG. 4 is a schematic representation of a semiconductor structure having a lattice transition layer with a constant composition;

FIG. 5 is a schematic representation of a semiconductor structure having a lattice transition layer with a graded composition;

FIG. 6 is a schematic representation of a semiconductor structure having a lattice transition layer with a graded composition, processed at a relatively high temperature;

FIG. 7 is a graph that comparatively illustrates the processing temperature profile for the lattice transition layers of FIGS. 4, 5 and 6;

FIGS. 8A, 8B and 8C are images obtained from Atomic Force Microscopy that show surface roughness for the lattice transition layers of FIGS. 4, 5 and 6, respectively;

FIG. 9 is a bar chart that shows the lattice transition layer dislocation density for CCTL, LTL1 and LTL2;

FIG. 10 is a graph that shows the current-gain characteristics for the device of FIG. 4;

FIG. 11 is a graph that shows the current-gain characteristics for the device of FIG. 5; and

FIG. 12 is a graph that shows the current-gain characteristics for the device of FIG. 6.

### DETAILED DESCRIPTION OF THE PREFERRED EMBODIMENTS

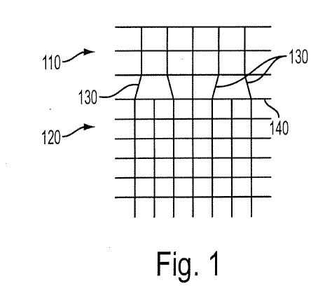

FIG. 1 is a schematic representation of a dislocation caused by layers having mismatching lattice constants. Referring to FIG. 1, substrate 120 can include, for example, one or more of the Groups III/V elements of the Periodic Table such as Indium Phosphide (InP) having a lattice constant of 5.8687 Å. Layer 1 is epitaxially grown over substrate 1 and comprises other elements of the Groups III/V of the Periodic Table. For example, layer 1 can be InAlAs with a lattice constant of 6.000 Å.

Layer 110 can be epitaxially grown over substrate 120. Layers 110 and 120 are separated by the crystalline boundary layer 140. Boundary layer 140 shows dislocation 130 which is caused by the lattice constant mismatch between substrate 120 and layer 110. In other words, strain relaxation of the lattice mismatch is accommodated by forming the dislocations 130 within the crystal structure. The dislocations degrade device performance as it scatters the movement of carriers and acts as a carrier trap and/or recombination center.

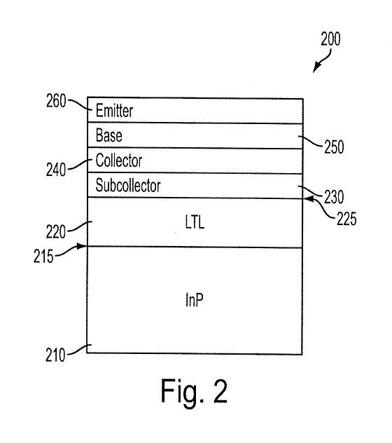

FIG. 2 is a schematic representation of an exemplary heterojunction bipolar transistor 200 according to one embodiment of the disclosure. The heterojunction bipolar transistor 200 includes substrate 210, lattice transition layer 220, subcollector 230, collector 240, base 250 and emitter 260. In the embodiment of FIG. 2, substrate 210 comprises InP with a lattice constant of about 5.880 A and subcollector layer 230 comprises InAlAs with a lattice constant of about 6.000-6.058 Å. Accordingly, there is a mismatch between the substrate and the subcollector layers.

To relieve the boundary layer strain caused by the mismatch between the lattice constants of the substrate and the subcollector, the lattice transition layer 220 is interposed between substrate 210 and subcollector 230. The lattice transition layer can be comprised of a plurality of epilayers grown on the substrate to form a graded transition layer. Since substrate 210 and subcollector 230 include elements of Groups III/V of the Periodic Table, lattice transition layer 220 may optionally include elements of Groups III/V. For example, lattice transition layer 220 can be InₓAl₁₋ₓAs, where 0.52<x<0.86.

The composition of the lattice transition layer may vary across its thickness to accommodate the different lattice constants for interface 215 and interface 225. For example, the composition of the lattice transition layer can be configured to decrease in aluminum content across the layer while increasing in arsenic content. According to an embodiment of the disclosure, the composition ratio of In/Al increases across the lattice transition layer from a first level to a second level such that the lattice constant of the lattice transition layer at interface 215 is commensurate with the lattice constant of substrate 210 while the lattice constant of the transition layer at interface 225 is commensurate with the lattice constant of subcollector 230.

The lattice transition layer can be grown over substrate 230 according to any of the conventional methods including chemical vapor deposition (CVD) and epitaxy. When epitaxially growing intermediate lattice transition layer 220, a plurality of InAlAs epilayers are sequentially deposited over substrate 210. Each epilayer can be deposited with a slightly different composition than the previous epilayer. Thus, the lattice transition layer can have a varying composition and a varying lattice constant to accommodate each of its adjacent layers.

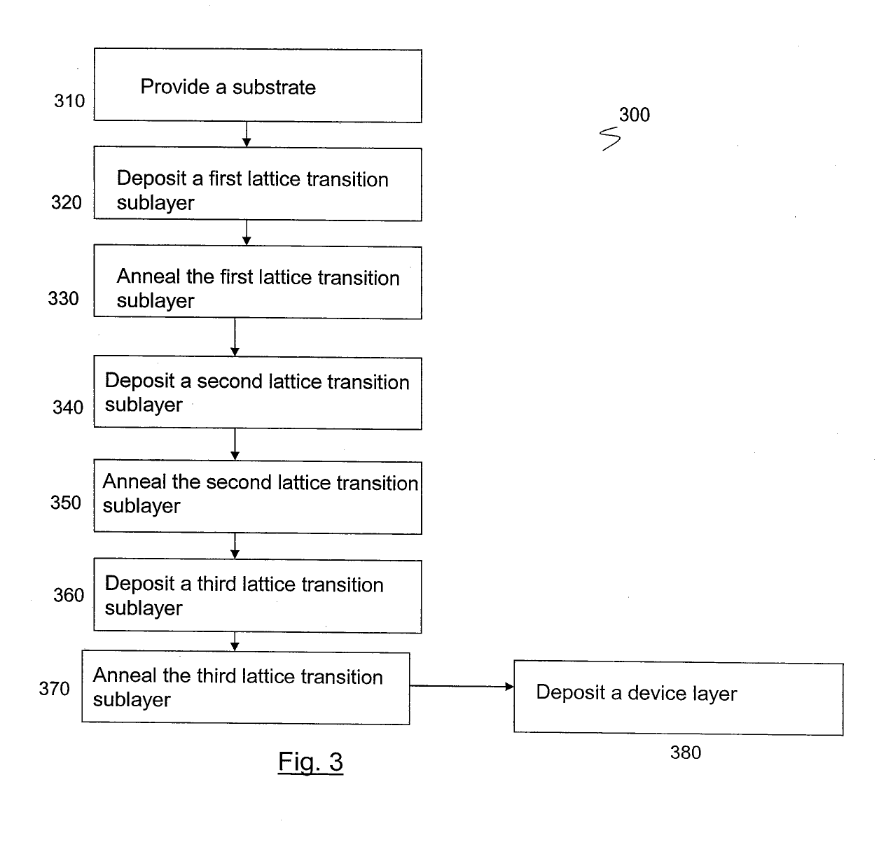

FIG. 3 is a schematic representation of a method for forming a lattice transition layer according to one embodiment of the disclosure. Process 300 of FIG. 3 starts with providing a substrate at step 310. The substrate may comprise any conventional material, including the elements of Groups III/V of the Periodic Table. In one embodiment, the substrate is a semi-insulating material such as InP.

At step 320, a first segment of the lattice transition layer is deposited over at least a portion of the substrate. In an exemplary implementation, a first lattice transition sublayer of InAlAs is deposited over the substrate. Step 320 can comprise several sub-steps. For example, if the lattice transition layer is grown epitaxially, step 320 can include the sub-steps of depositing multiple epilayers over the substrate. The composition of the first epilayer can be configured to provide a lattice parameter commensurate to that of the substrate. The compositions of the subsequent epilayers can deviate slightly from the composition of the first epilayer in order to create gradation throughout the lattice transition layer. The composition of the final epilayer can be configured to provide a lattice constant commensurate to that of a device layer such as the subcollector 230 of FIG. 2. The epitaxial deposition can be implemented at an enclosed reactor. In one embodiment, the deposition temperature is constant throughout the deposition step.

In another embodiment, the deposition reactor is an ultra-high vacuum which is maintained at nonequilibrium growth conditions by introducing one or more gasses including elements from Groups III/V of the Periodic Table. Thus, the deposition step is enhanced by pressurizing the reactor with, for example, arsenic gas and absent an oxidizing environment.

While the optimal deposition temperature and group V/III flux ratio are dependent on the composition of the epilayers, a V/III ratio of about 10 to 20 and a deposition temperature of about 450 to 520° C., obtained by optical pyrometry, have been applied successfully.

Once the first lattice transition sublayer has achieved the desired thickness, it can be annealed to relieve stress at step 330. The annealing time and temperature will vary depending on the thickness and the composition of the sublayer. In one embodiment, the first sublayer can be annealed at a temperature of about 600-550° C. for about 5 to 10 minutes

At step 340, a second lattice transition sublayer is deposited over the first sublayer. The composition of the second sublayer can also be graded. The second lattice transition sublayer can be deposited under constant temperature and under Groups III/V overpressure. At step 350, the second lattice transition sublayer is annealed to relieve stress. Similarly, at step 360, a third lattice transition sublayer is deposited over at least a portion of the second sublayer. The third lattice transition sublayer is annealed at step 370 under conditions similar to that of the first and the second sublayers. Finally, at step 380, a device layer such as a subcollector layer is deposited over at least a portion of the third sublayer. The device layer can define a diode, a quantum-well laser structure, a single heterojunction bipolar transistor and a double heterojunction bipolar transistor.

A combination of the first, second and third lattice transition sublayers defines an intermediate lattice transition layer. The intermediate lattice transition layer can be processed as three separate sublayers to illustrate an embodiment of the disclosure in which the lattice transition layer is annealed during the deposition. In another embodiment, the annealing step can be implemented as a single step after the lattice transition layer has been deposited.

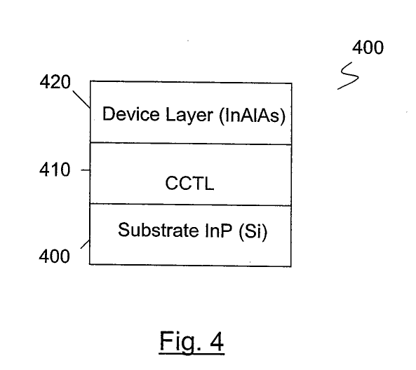

Examples—Identical device layers were grown on three different lattice transition layer to investigate the influence of buffer layer defects on device performance. In each case, the substrate was InP (SI) and the device layer, InAlAs, contained 85% Indium. FIGS. 4, 5 and 6 schematically illustrate the three samples.

Specifically, FIG. 4 is a schematic representation of a semiconductor structure having a lattice transition layer with constant composition. In FIG. 4, substrate 402 supports constant composition transition layer (“CCTL”) 410 and device layer 420. CCTL 410 represents a conventional lattice transition layer with uniform composition (InAlAs) which was epitaxially grown over substrate 400. CCTL 410 was not annealed prior to depositing device layer 420.

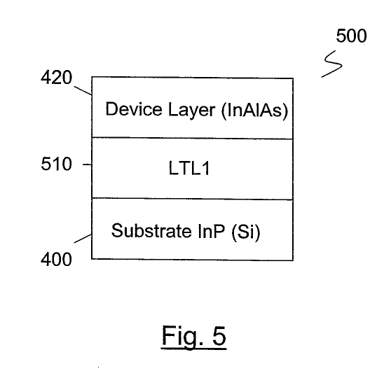

FIG. 5 is a schematic representation of a semiconductor structure having a lattice transition layer with graded composition. In FIG. 5, substrate 400 supports lattice transition layer 510 and device layer 420. For brevity, conventional lattice transition layer 510 will be referred to as LTL1. LTL1 was epitaxially grown over substrate 400 under a declining deposition temperature. The composition of LTL1 varied across its thickness according to the formula: InₓAl₁₋ₓAs, where 0.52<x<0.86. During deposition, the aluminum content of LTL1 510 was decreased through evaporation and its arsenic content was increased through expitaxy. LTL1 was not annealed prior to depositing device layer 454.

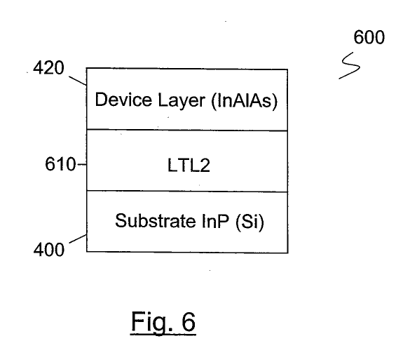

FIG. 6 is a schematic representation of a semiconductor structure having a lattice transition layer with a graded composition and processed at a relatively high temperature. Referring to FIG. 6, substrate 400 supports lattice transition layer 610 and device layer 420. For brevity, intermediate lattice transition layer 610 will be referred to as LTL2. LTL2 was epitaxially grown over substrate 400 under a relatively high constant temperature while maintaining an overpressure of at least one element from Groups III/V of the Periodic Table. The composition of LTL2 varied across its thickness according to the formula: InₓAl₁₋ₓAs, where 0.52<x<0.86. In accordance with an embodiment of the disclosure, the deposition process was interrupted intermittently to anneal the deposited epilayers. Device layer 420 was deposited over LTL2.

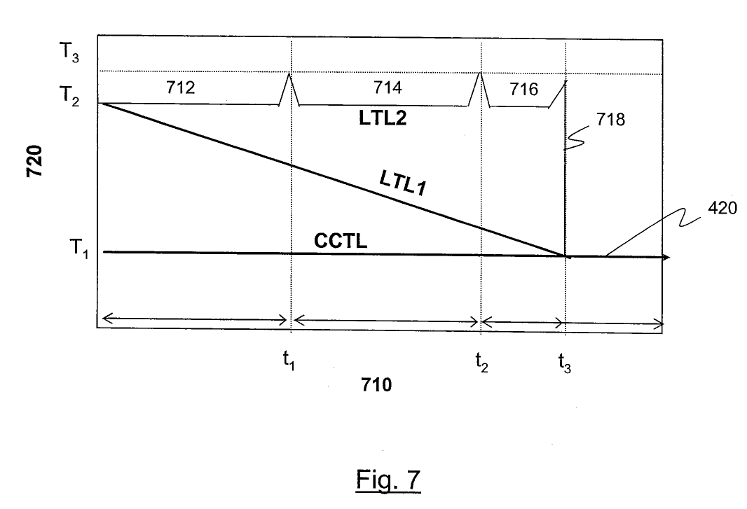

FIG. 7 comparatively illustrates the processing temperature profile for the lattice transition layers of FIGS. 4, 5 and 6. In FIG. 7, the x-axis 710 represents the buffer layer thickness during the deposition process and the y-axis 720 represents the reactor temperature during the deposition process. The total thickness (t3) for each of the lattice transition layers CCTL, LTL1 and LTL2 was about 0.9 μm.

CCTL had a composition of In_{0.86}Al_{0.14}As and was deposited at constant temperature 420° C. CCTL was not annealed. Device layer 420 was then deposited over the CCTL. The layers were deposited by Molecular Beam Epitaxy at 550° C.

LTL1 was epitaxially grown over a declining temperature (T₂−T₁) and without annealing. The starting temperature T₂ was about 520° C. The composition of LTL1 was graded (InₓAl₁₋ₓAs; 0.52-0.86) by decreasing the aluminum content while increasing the arsenic content.

LTL2 was deposited over a relatively high and constant temperature of about 520° C., which is at or near the desorbtion temperature of the substrate. The deposition process was interrupted at layer thicknesses t₁, t₂ and t₃ for annealing and sublayers 712, 714 and 716 were annealed to relieve dislocation stress. The annealing temperature, T₃, was about 620° C. Each of sublayers 712, 714 and 716 included one or more epilayers. Finally, the temperature 718 was drastically reduced to T₁ after annealing the third sublayer 716 and before depositing device layer 420 over the LTL2.

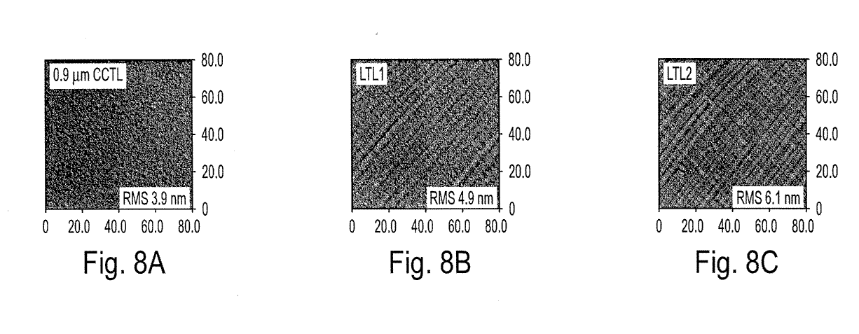

The surface roughness of CCTL, LTL1 and LTL2 were measured by electron microscopy with the results illustrated in FIGS. 8A-8C, and tabulated at Table 1 below. The results indicate that CCTL had the lowest surface roughness of about 3.9 nm, LTL1 had a surface roughness of about 4.9 nm and LTL2 had surface roughness of about 6.1 nm. However, note that even though the RMS roughness is greater in the case of LTL2, it can be traded off for enhanced reduction in threading dislocation density which has a much more pronounced effect on device performance. [Inventors—Is there any significance to the cross-hatched pattern in LTL1 and LTL2?]

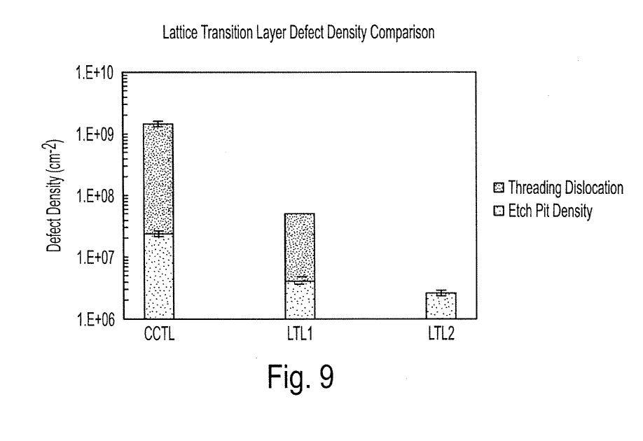

High resolution X-ray diffraction (HRXRD) analysis was conducted to identify threading dislocation relaxation in each of CCTL, LTL1 and LTL2. The results show threading dislocation relaxation of about 94%, 90% and 100% for CCTL, LTL1 and LTL2, respectively. Finally, plain view transmission electron microscopy (PVTEM) was used to measure etch pit density (EPD) and threading dislocation density for each of CCTL, LTL1 and LTL2. The results are shown in FIG. 9. It can be seen from FIG. 9 that the high temperature treatment drastically reduces the EPD in the intermediate transition layers. FIG. 9 also shows that no threading dislocation was observed in LTL2. The experimental results are tabulated at Table 1 as follows:

TABLE 1
Intermediate Transition Layer Characterization Summary

| | | | | Dislocation | Peak to |
|---|---|---|---|---|---|
| | Roughness | Relaxation | EPD | Density | Valley |
| | (nm) | % | (cm⁻²) | (cm⁻²) | Roughness |
| CCTL | 2.9 | 94 | 2.5 × 10⁷ | 1.8 × 10⁹ | 21 |
| LTL1 | 4.9 | 90 | 5 × 10⁶ | 4.0 × 10⁷ | 25 |
| LTL2 | 6.1 | 100 | 3 × 10⁶ | 0 | 27 |

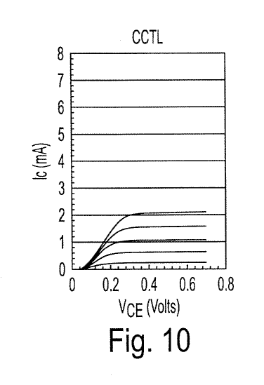

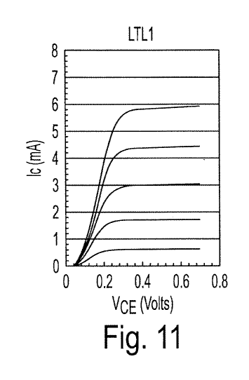

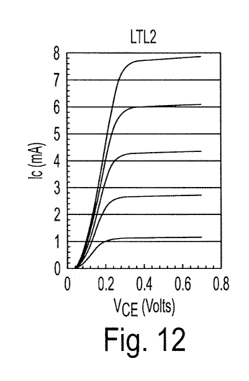

FIGS. 10, 11 and 12 show current-gain characteristics for the devices shown in FIGS. 4, 5 and 6, respectively. More specifically, FIG. 10 shows the current-gain characteristics of semiconductor device 400 of FIG. 4; FIG. 11 shows the current-gain characteristics of semiconductor device 500 of FIG. 5; and FIG. 12 shows the current-gain characteristics of semiconductor device 600 of FIG. 6. By comparing the current-gain characteristics shown in FIGS. 10-12, it can be readily seen that device 420 grown on LTL2 advantageously has the highest common-emitter current-gain (80) and the device 420 grown on CCTL has the lowest current-gain (21).

Finally, the performance characteristics of LTL2 are entirely unexpected. Given that the deposition temperature was maintained at 600° C. which is at or near the desorbtion temperature of the substrate, one of ordinary skill in the art would expect that aluminum and arsenic would sublimate during deposition, resulting in a defective intermediate transition layer. Indeed, the conventional methodology of reducing the deposition temperature (see FIG. 5, temperature reduction T₂ to T₁) was devised to avoid this very problem. However, as demonstrated, the embodiments disclosed herein overcome these and other deficiencies to produce an intermediate lattice transition layer superior in threading dislocation density and performance characteristics.

The embodiments described herein are exemplary and non-limiting. The scope of the disclosure is defined solely by the appended claims when accorded a full range of equivalence with many variations and modifications naturally occurring to one of ordinary skill in the art without departing from the scope of the claims.

What is claimed is:

1. A method for forming an intermediate lattice transition buffer layer, the method comprising the steps of:
(a) depositing a first graded InAlAs layer on a substrate at a first constant temperature, the first graded InAlAs layer having an In/Al composition ratio which increases across the buffer layer from a first level to a second level;
(b) annealing at least the first graded InAlAs layer;
(c) depositing a second graded InAlAs layer on the first graded InAlAs layer at the first constant temperature, the second graded InAlAs layer having an In/Al composition ratio which increases across the buffer layer from the second level to a third level; and
(d) annealing at least the second graded InAlAs layer;
the buffer layer being formed under Groups III/V overpressure.

2. The method of claim 1, wherein the step of depositing a first graded InAlAs layer further comprises epitaxially growing a plurality of InAlAs epilayers on the substrate.

3. The method of claim 2, wherein a first of the plurality of epilayers further comprises a lattice parameter substantially equal to a lattice parameter for the substrate.

4. The method of claim 1, wherein the step of depositing a first graded InAlAs layer further comprises epitaxially growing an InAlAs player on the substrate.

5. The method of claim 1, wherein the step of depositing a first graded InAlAs layer further comprises depositing InAlAs with molecular beam apiary.

6. The method of claim 1, wherein annealing at least one of the first graded InAlAs layer or the second graded InAlAs layer at a temperature range of about 450 to 550° C.

7. The method of claim 1, further comprising:
(a) decreasing the temperature form the first constant temperature to a second temperature to accommodate device layer growth.

8. The method of claim 1, wherein the buffer layer is formed under an As overpressure.

9. The method of claim 1, wherein the group V/III ratio is in the range of about 10 to 20.

10. A semiconductor structure formed by the method of claim 1.

11. A semiconductor device incorporating the buffer layer of claim 1.

12. A semiconductor device comprising:
a substrate;
a lattice transition layer that is not more than 1 micron thick, with a surface roughness height of not more than 4 nm and an etch pit density of not more than 1×10⁶ 1/cm².

13. The semiconductor device of claim 12, wherein the lattice transition layer is a graded buffer layer.

14. The semiconductor device of claim 12, wherein the lattice transition layer further comprises a plurality of epilayers.

15. The semiconductor device of claim 12, wherein the lattice transition layer has a lattice parameter in the rage of about 6.000-6.058 Å.

16. The semiconductor device of claim 12 wherein the lattice transition layer has a lattice parameter in the range of about 5.6584 to 6.2 Å.

17. The semiconductor device of claim 12, wherein the lattice transition layer further comprises a lower surface adjacent to the substrate and an upper surface adjacent to the device layer and wherein a lattice parameter the lower surface is within 2% of a lattice parameter of the upper surface.

18. The semiconductor device of claim 12, wherein the semiconductor apparatus is selected from the Groups consisting of a diode, a quantum-well laser structure, a single hetero junction bipolar transistor and a double hetero junction bipolar transistor.

19. The semiconductor device of claim 12, wherein the lattice transition layer comprises a graded composition of InAlAs layer with the In/Al composition ratio increasing across a thickness of lattice transition layer.

20. A method for growing a lattice transition layer having a varying lattice constant, the method comprising the steps of:
epitaxially growing a first lattice transition sublayer over a substrate at a first temperature;
annealing the first lattice transition sublayer at a second temperature to provide strain relaxation at the first lattice transition sublayer;
epitaxially growing a second lattice transition sublayer over the first lattice transition sublayer at the first temperature;
annealing the second lattice transition sublayer at a third temperature to provide strain relaxation at the second lattice transition sublayer;
reducing the temperature to a temperature suitable for depositing a device layer; and depositing the device layer;
wherein each of the first lattice transition sublayer and the second lattice transition sublayer are substantially free of threading dislocation density.

21. The method of claim 20, wherein at least one of the first lattice transition layer and the second lattice transition layer is substantially free of threading dislocation.

22. The method of claim 20, wherein at least one of the first sublayer or the second sublayer further comprises a plurality of epilayers.

23. The method of claim 20, further comprising maintaining an overpressure of at least one element representative of Groups III/V of the Periodic Table.

24. The method of claim 20, wherein the second temperature and the third temperature are substantially identical.

25. The method of claim 20, wherein the first temperature is at or near the desorbtion temperature of the substrate.

26. The method of claim 20, wherein the substrate is InP.

27. The method of claim 20, wherein the first sublayer is one of InAlAs or InGaAs.

28. The method of claim 20, wherein the second sublayer is one of InAlAs or InGaAs.
